(19) United States
(12) Patent Application Publication
(10) Pub. No.: US 2002/0063336 A1
(43) Pub. Date: May 30, 2002

(54) Semiconductor device and method for manufacturing semiconductor device

(75) Inventor: Naoteru Matsubara, Gifu-ken (JP)

Correspondence Address: ARMSTRONG,WESTERMAN & HATTORI, LLP, 1725 K STREET, NW., SUITE 1000, WASHINGTON, DC, 20006, US

(73) Assignee: Sanyo Electric Co. , Ltd, Moriguchi-shi (JP)

(21) Appl. No.: 09/995,580

(22) Filed: Nov. 29, 2001

(30) Foreign Application Priority Data
Nov. 30, 2000 (JP) 2000-365787

(51) Int. Cl. H01L 23/48

(52) U.S. Cl. 257/758

(57) ABSTRACT

A semiconductor device that prevents the dispersion of copper and is optimal for high speed operation. The semiconductor device includes an interlayer dielectric film formed on a lower wiring layer. The interlayer dielectric film has a groove. A contact plug and a copper line are formed in the groove. A barrier metal formed between the groove and the contact plug and the barrier metal serves to prevent contact between copper and the dielectric film. The upper surface of the copper line is coated with a modified SOG film in which ions are implanted. The barrier metal and the modified SOG film decrease the dispersion of copper.

### BACKGROUND OF THE INVENTION

The present invention relates to a semiconductor device having lines that include copper and a method for manufacturing such semiconductor memory device.

Due to the higher integration, higher density, and higher operating speed of semiconductor devices, the semiconductor devices must be wired by lines having high performance. Such lines are often formed from aluminum. However, electromigration is apt to occur when using aluminum lines. Therefore, copper has been receiving more attention as the material for semiconductor device lines since the resistance of copper is lower than that of aluminum and since electromigration seldom occurs when using copper. Copper is expected to increase the operating speed and prolong the life of semiconductor devices.

Conventional copper lines are formed through a damascene process, which will now be discussed. When performing the damascene process, grooves are first formed in a dielectric film, which has a flat surface. The grooves are then filled with a metal material. The metal material is then removed so that the upper surface of the metal material becomes flush with the surface of the dielectric film. This forms the metal lines. The damascene process provides a relatively simple method for manufacturing metal lines and facilitates the formation of copper lines, which cannot be formed through dry etching.

The manufacturing of copper lines through the damascene process will now be discussed with reference to FIGS. 1A to 1E.

Referring to FIG. 1A, a first silicon oxide film 102 is applied to a silicon substrate 101 through a plasma chemical vapor deposition (CVD) process. The plasma CVD process is further performed to superimpose a first silicon nitride film 103 and a second silicon oxide film 104 one after another on the silicon substrate 101. The first silicon nitride film 103 is used as an etch stopper in a subsequently performed process.

Then, referring to FIG. 1B, a first resist pattern 110 is formed on the second silicon oxide film 104. Anisotropy etching is performed using the first resist pattern 110 as a mask to form contact holes 120, which electrically connect wiring layers of two different phases.

After removing the first resist pattern 110, referring to FIG. 1C, a second resist pattern 111, which is used to form copper lines, is formed. The second silicon oxide film 104 is then etched using the second resist pattern 111 as a mask and using the first silicon nitride film 103 as a stopper film. This forms wiring grooves 121.

Then, referring to FIG. 1D, copper 131 is filled in the contact holes 120 and the wiring grooves 121 after applying a barrier metal 130 to the walls of the contact holes 120 and the wiring grooves 121. A chemical mechanical polish (CMP) process, which uses the second silicon oxide film 104 as a stopper, is performed to grind and flatten the upper surfaces of the barrier metal 130 and the copper 131. This forms copper lines 121W and contact plugs 120W. The barrier metal 130 prevents the copper 131 from being dispersed in the first and second silicon oxide films 102, 104.

Finally, referring to FIG. 1E, a second silicon nitride film 105 is formed on the second silicon oxide film 104 and the copper lines 121W by performing the plasma CVD process. The second silicon nitride film 105 prevents the dispersion of copper from the upper surface of the copper lines 121W.

The barrier metal 130 prevents sideward dispersion of the copper 131, and the second silicon nitride film 105 prevents upward dispersion of the copper 131. This manufactures a semiconductor device 100 that is provided with copper lines, avoids electromigration, and has a low resistance.

The conductivity of the wiring material and the permittivity of the dielectric material, which surrounds the wiring, affect the operating speed of the semiconductor device 100. In other words, the formation of lines between dielectric films, which having a large permittivity, increases the capacitance of the lines and makes it difficult to increase the speed of the semiconductor device. Accordingly, it is preferred that the dielectric film be formed from a material having a relatively low permittivity, such as fluorine-added silicon oxide, organic spin on glass (SOG), inorganic SOG, or organic polymer.

However, when the dielectric film is formed from such material, it becomes difficult to prevent the dispersion of the copper 131. When forming the dielectric film from such material, a shield, or the barrier metal 130, is arranged between the copper 131 and the dielectric films to prevent the dispersion of the copper 131. In this manner, the barrier metal 130, which is made of metal, is used to shield the copper 131. This prevents the capacitance from increasing and suppresses the dispersion of the copper 131.

The upper surfaces of the copper lines 121W are removed so that the upper surfaces of the copper lines 121W become flush with the upper surface of the second silicon oxide film 104. The barrier metal 130 cannot be arranged on the upper surfaces of the lines 121W and the second silicon oxide film 104 since this may result in short-circuiting of the lines 121W. Thus, the second silicon nitride film 105 is formed on the upper surface of the copper 131 to shield and prevent the dispersion of the copper 131. However, the permittivity of the second silicon nitride film 105 is relatively high. This makes it difficult to increase the speed of the semiconductor device.

Further, the above preferred materials, which permittivity are relatively low, cannot be used in lieu of the second silicon nitride film 105 since they cannot prevent the dispersion of the copper 131. Hence, the material of the dielectric film used to coat the copper lines 121W was limited. This applies restrictions to the designing of the semiconductor device.

The problem that occurs when shielding copper also occurs in semiconductor devices having copper lines formed through techniques other than the damascene process.

### SUMMARY OF THE INVENTION

It is an objective of the present invention to provide a semiconductor device and a method for manufacturing the semiconductor device that prevents dispersion of copper and enables operation at higher speeds.

It is a further objective of the present invention to provide a semiconductor device, which has a copper wiring, that reduces designing restrictions.

To achieve the above objectives, the present invention provides a semiconductor device including a first dielectric film having an opening and a line arranged in the opening. The line includes copper. A second dielectric film coats at least part of the line. Impurities are implanted in the second dielectric film.

A further perspective of the present invention is a semiconductor device including a first dielectric film having an opening, and a line arranged in the opening. The line includes copper. A second dielectric film coats at least part of the line. The second dielectric film is formed from a low permittivity material in which impurities are implanted.

A further perspective of the present invention is a semiconductor device including a silicon substrate having a first dielectric film. The first dielectric film has an upper surface and a groove. A copper line is formed in the groove and has an upper surface. The upper surface of the copper line is flush with the upper surface of the first dielectric film. A second dielectric film coats the upper surface of the copper line and the upper surface of the first dielectric film. Impurities are implanted in the second dielectric film.

A further perspective of the present invention is a method for manufacturing a semiconductor device. The method includes forming a first dielectric film on a lower wiring layer, forming a groove in the first dielectric film, filling the groove with copper by way of a barrier metal, coating at least part of the upper surface of the copper with a low permittivity dielectric material, and modifying the low permittivity dielectric material by implanting impurities.

Other aspects and advantages of the present invention will become apparent from the following description, taken in conjunction with the accompanying drawings, illustrating by way of example the principles of the invention.

### BRIEF DESCRIPTION OF THE DRAWINGS

The invention, together with objects and advantages thereof, may best be understood by reference to the following description of the presently preferred embodiments together with the accompanying drawings in which:

FIGS. 1A to 1E are cross-sectional views illustrating the procedures for manufacturing a prior art semiconductor device;

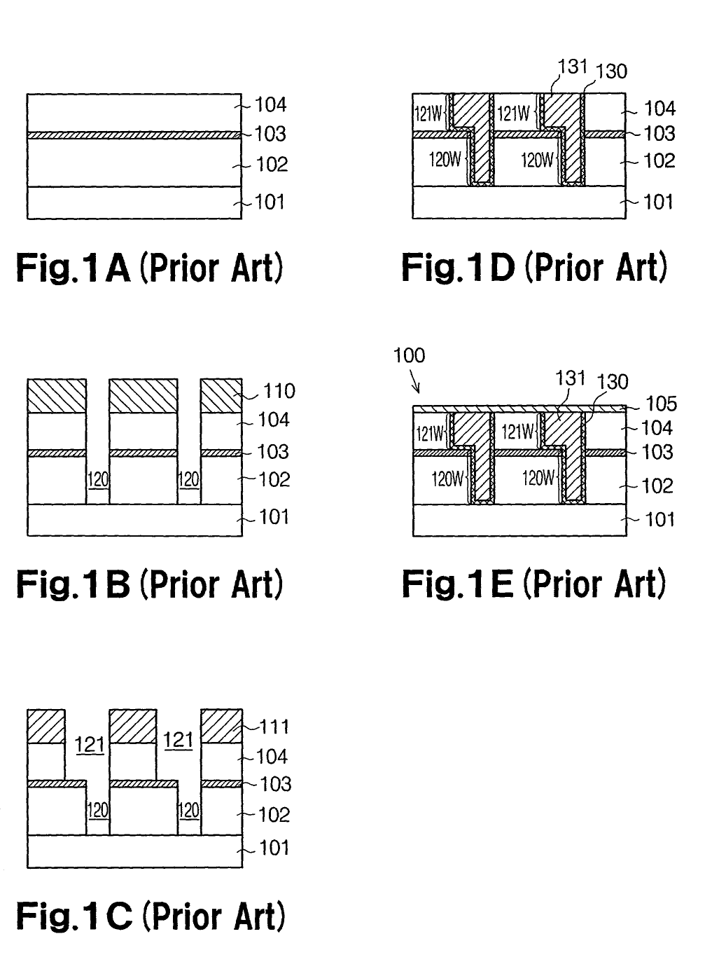

FIG. 2 is a cross-sectional view showing a semiconductor device according to a preferred embodiment of the present invention;

FIGS. 3A to 3F are cross-sectional views showing the procedures for manufacturing the semiconductor device of FIG. 2; and

FIGS. 4A and 4B are graphs illustrating the copper dispersion concentration in the semiconductor device of FIG. 2; and

FIGS. 4C and 4D are graphs illustrating the copper dispersion concentration in the prior art semiconductor device.

### DETAILED DESCRIPTION OF THE PREFERRED EMBODIMENTS

A semiconductor device 50 according to a preferred embodiment of the present invention will now be discussed.

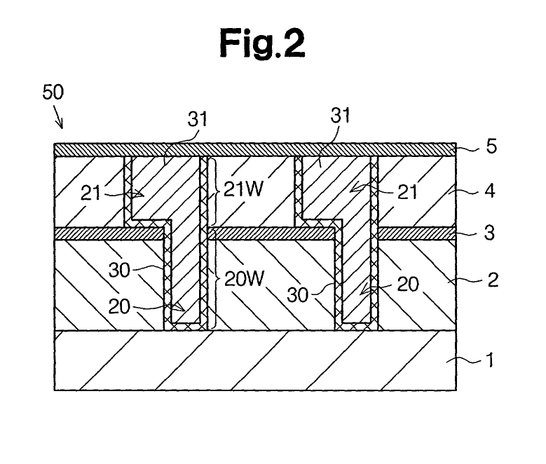

FIG. 2 is a cross-sectional view showing the semiconductor device 50. The semiconductor device 50 includes a silicon substrate 1, or a lower wiring layer, and first, second, and third interlayer dielectric films 2, 3, 4, which are superimposed on the substrate 1. The first and third interlayer dielectric films 2, 4 are first and second silicon oxide films 2, 4, preferably made of SiO. The second interlayer dielectric film 3 is a silicon nitride film 3 preferably made of SiN.

Contact holes 20 are formed in the first silicon oxide film 2 and the silicon nitride film 3. Wiring grooves 21 are formed in the second silicon oxide film 4 to form copper lines (copper wiring) 21W.

Contact plugs 20W are formed in the contact holes 20. Copper lines 21W are formed in the wiring grooves 21. The contact plugs 20W electrically connect the lower wiring layer (silicon substrate) 1 and the copper lines 21W via the first and second interlayer dielectric films 2, 3 (first silicon film 2 and silicon nitride film 3). The contact plugs 20W and the copper lines 21W substantially include copper 31 and a barrier metal 30. The barrier metal 30 is formed between the copper 31 and the walls of the contact holes 20 and between the copper 31 and the walls of the wiring grooves 21. The barrier metal 30 prevents contact between the copper 31 and the walls of the contact holes 20 and between the copper 31 and the walls of the wiring grooves 21. This prevents the copper 31 from being dispersed in the substrate 1 and the interlayer dielectric films 2, 3, 4.

It is preferred that the barrier metal 30 be formed from titanium (Ti) and tantalum (Ta), titanium nitride (TiN) and tantalum nitride (TaN), or titanium tungsten (TiW) and tungsten tantalum (TaW).

A modified SOG film 5 coats the copper lines 21W and the second silicon oxide film 4. The modified SOG film 5 is formed by implanting impurities such as argon ions (Ar⁺) in a material having a relatively low permittivity. Accordingly, the modified SOG film 5 has a relatively low permittivity and prevents the dispersion of the copper 31. Thus, the dispersion of the copper 31 from the upper surface of the copper lines 21W is sufficiently suppressed. Further, higher operating speeds of the semiconductor device 50 is enabled.

A method for manufacturing the semiconductor device 50 of the preferred embodiment will now be discussed.

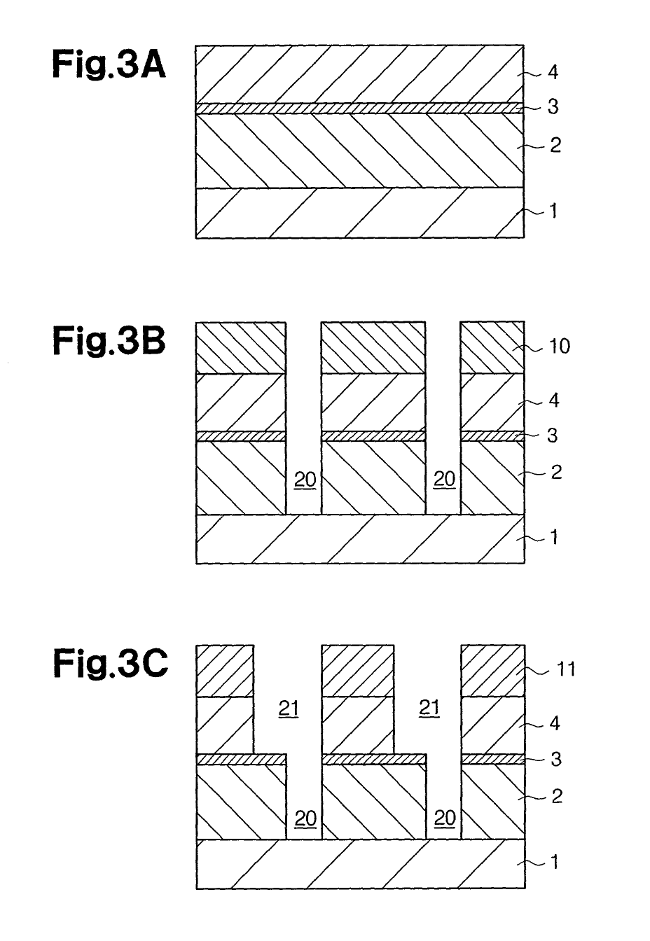

Referring to FIG. 3A, the first silicon oxide film 2 is applied to the silicon substrate 1 by performing the plasma CVD process. The thickness of the first silicon oxide film 2 is, for example, 500 nm. The silicon nitride coating 3, which functions as a stopper coating, is then formed on the first silicon oxide film 2 by performing the plasma CVD process. The thickness of the silicon nitride film 3 is, for example, 50 nm. The second silicon oxide film 4 is then formed on the silicon nitride film 3. The thickness of the second silicon oxide film 4 is, for example, 400 nm.

It is preferred that the gases used when forming the first and second silicon oxide films 2, 4 be monosilane and nitrous oxide, monosilane and oxygen, or tetraethylorthosilicate (TEOS) and oxygen. Further, it is preferred that the temperature be 300° C. to 900° C. when forming the silicon oxide films 2, 4.

Then, referring to FIG. 3B, a lithography process is performed to form a first resist pattern 10, which is used to form the contact holes 20. Using the first resist pattern 10 as a mask, anisotropy etching is performed on the second silicon oxide film 4, the silicon nitride film 3, and the first silicon oxide film 2 to form the contact holes 20. The first resist pattern 10 is then removed.

Referring to FIG. 3C, a lithography process is performed to form a second resist pattern 11, which is used to form copper lines. Using the second resist pattern 11 as a mask and the silicon nitride film 3 as a stopper, anisotropy etching is performed on the second silicon oxide film 4 to form the wiring grooves 21.

Then, as shown in FIG. 3D, a sputtering process and a CVD process are performed to form the barrier metal 30 in the contact holes 20 and the wiring grooves 21. The thickness of the barrier metal 30 is, for example, about 50 nm.

A sputtering process, a CVD process, and a plating process are performed to deposit copper 31 in the contact holes 20 and the wiring grooves 21 to a thickness of, for example, about 700 nm. A CMP process is performed to grind and remove the surplus barrier metal and copper deposited above the upper surface of the silicon oxide film. As a result, the upper surfaces of the barrier metal 30 and the copper 31 become flush with the upper surface of the second silicon oxide film 4. This forms the copper lines 21W.

Then, referring to FIG. 3E, an organic SOG film 5a is formed on the copper lines 21W and the second silicon oxide film 4. The thickness of the organic SOG film Sa is, for example, about 100 nm. The method for forming the organic SOG film 5a will now be discussed in detail.

(1) First, a predetermined silicon compound is dissolved in a predetermined alcohol solvent to prepare an organic SOG solution. It is preferred that the silicon compound be a compound represented by the composition formula of CH₃Si(OH)₃. Further, it is preferred that the predetermined alcohol solvent be a solvent formed from the mixture of isopropyl alcohol (IPA) and acetone.

(2) The silicon substrate 1 is then rotated for 20 seconds at a rotating speed of 5,500 rpm. Such spin coating develops the organic SOG solution and coats the upper surface of the second silicon oxide film 4 and the copper lines 21W with the organic SOG solution.

(3) In a nitrogen atmosphere, the silicon substrate 1 is heat treated at temperatures 100° C., 150° C., 200° C., and 22° C. The heat treatment is performed for one minute at each temperature. This evaporates alcohol from the developed organic SOG solution and forms the organic SOG film 5a. The heat treatment conditions (temperature and time) in the preferred embodiment is set so that the heat treatment does not disperse the copper 31. In the prior art, after the heat treatment is performed at 22° C., heat treatment was performed at about 400° C. for about 30 minutes. However, in the preferred embodiment, the heat treatment that was performed at about 400° C. is unnecessary.

Referring to FIG. 3F, an ion implantation process is then performed to dope argon ions (Ar⁺) in the organic SOG film 5a. The ion implantation enhances polymerization in the organic SOG film 5a. As a result, organic components are decomposed in the modified SOG film 5, and the modified SOG film 5 becomes dense. It is preferred that the argon ions be doped under conditions in which the acceleration energy is 25 KeV and the implantation amount is 1×10¹⁵ atoms/cm².

The dispersion suppression effect of the copper 31 will now be discussed.

An experiment using four types of film samples was conducted to test the dispersion suppression effect of the copper 31.

(1) A modified SOG film, an organic SOG film, a silicon nitride film, and a silicon oxide film were used as the film samples. The film samples were applied to a silicon substrate. Each film sample had a thickness of about 0.3 μm.

(2) A copper film having a thickness of 0.3 μm was then applied to each film sample.

(3) Heat treatment was then performed on the silicon substrate at a temperature of about 400° C. for three hours in a nitrogen atmosphere.

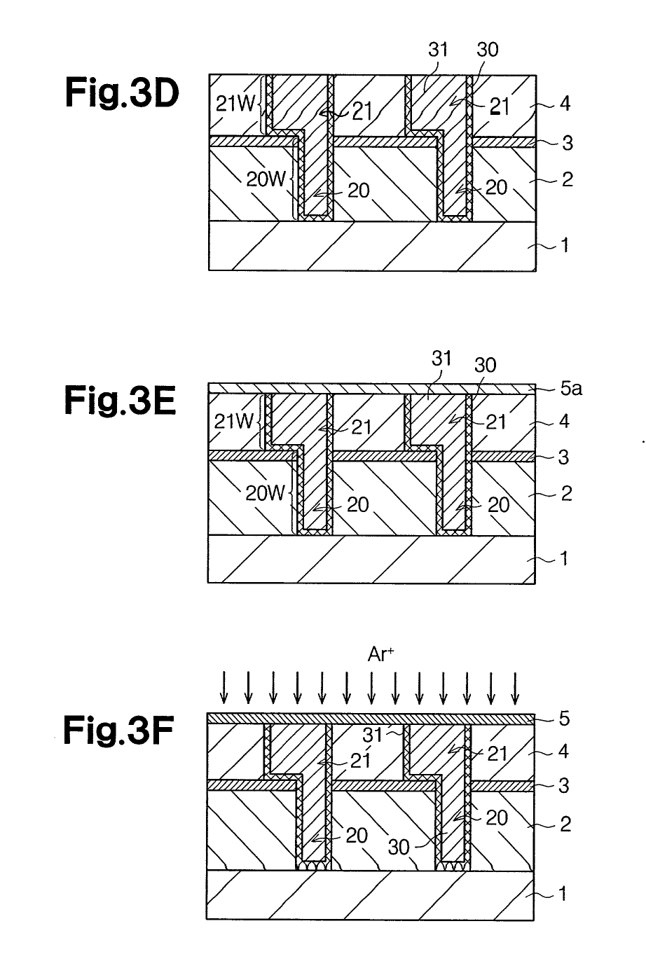

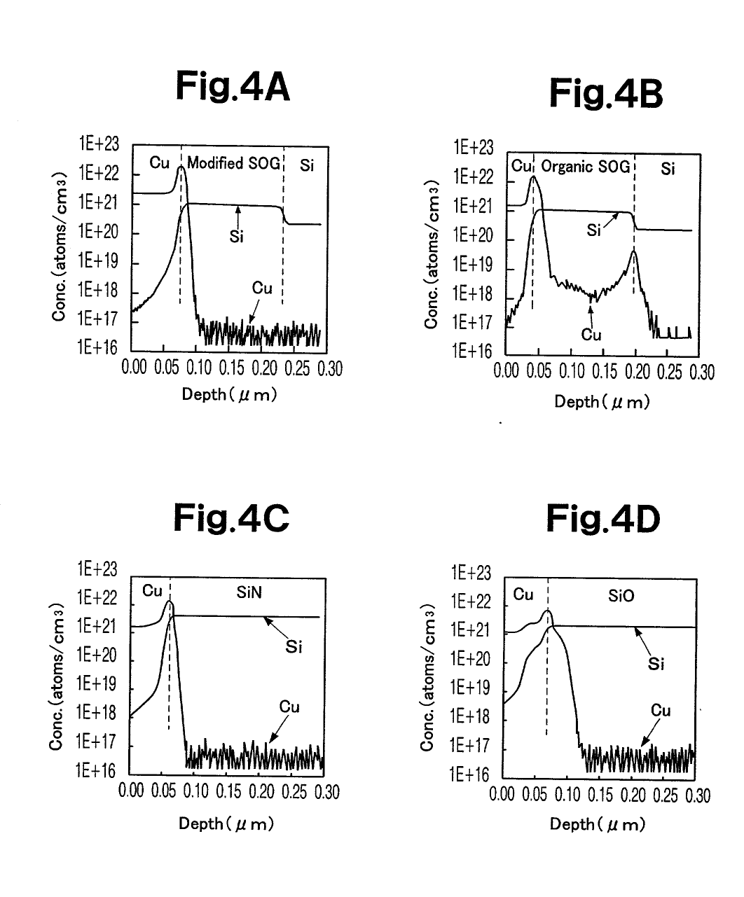

(4) A secondary ion mass spectroscopy (SIMS) method was performed to confirm the heat dispersion of copper in each film sample. The results are shown in FIGS. 4A to 4D.

FIG. 4A is a graph illustrating the effect of the modified SOG film. FIG. 4B is a graph illustrating the effect of the organic SOG film. FIG. 4C is a graph illustrating the effect of the silicon nitride film. FIG. 4D is a graph illustrating the effect of the silicon oxide film. In each graph, the vertical axis represents the concentration of copper and silicon, and the lateral axis represents the distance from the upper surface of the copper film (depth).

In the modified SOG film, as shown in FIG. 4A, the concentration of copper suddenly decreases from the interface between the copper film and the modified SOG film as the depth increases. The concentration of copper becomes minimal from the depth of about 0.25 μm.

The dispersion suppression effect of the modified SOG film is superior to that of the organic SOG film, as shown in FIG. 4B, and that of the silicon oxide film, as shown in FIG. 4D. Further, the dispersion suppression effect of the modified SOG film is about the same as the silicon nitride film, as shown in FIG. 4C.

The relative permittivity of the modified SOG film is about 3.7 and lower than that of the silicon nitride film, which is about 7. Accordingly, the modified SOG film is meritorious in that it is a dielectric film that sufficiently suppresses the dispersion of copper even though it does not increase the wiring capacitance. Thus, the modified SOG film is optimal for use as a dielectric film that coats copper lines.

The preferred embodiment has the advantages discussed below.

(1) The modified SOG film 5, which coats the upper surface of the copper lines 21W, sufficiently suppresses the dispersion of the copper 31. Further, the relatively low permittivity of the modified SOG film 5 prevents the wiring capacitance from increasing. Thus, the semiconductor device 50 is capable of high speed operation.

(2) The dielectric film 5, in which impurities are implanted, decreases the dispersion of the copper 31. This increases the reliability of the semiconductor device 50.

(3) The modified SOG film 5 is formed by implanting impurities such as argon ions. In other words, the implantation of impurities enables the usage of materials (the organic SOG film 5a) that could not be used as the dielectric film of the copper lines 21W. This allows the semiconductor device 50 to be designed with fewer restrictions.

(4) The surfaces defining openings, or the side walls and bottom walls of the contact holes 20 and the wiring grooves 21, are covered by the barrier metal 30. This suppresses the dispersion of the copper 31. Further, the modified SOG film 5 coats the copper lines 21W. This suppresses the dispersion of the copper 31 from the upper surface of the copper lines 21W. The permittivity of the modified SOG film 5 is low. Thus, the semiconductor device 50, the lines 21W of which includes the copper 31, prevents the dispersion of the copper and is capable of high speed operation.

It should be apparent to those skilled in the art that the present invention may be embodied in many other specific forms without departing from the spirit or scope of the invention. Particularly, it should be understood that the present invention may be embodied in the following forms.

If the etching process can be controlled with high accuracy, the silicon nitride film 3, which functions as a stopper film, may be eliminated.

When forming the wiring groove 21, the silicon nitride film 3 may be completely removed. This eliminates the effects of the silicon nitride film 3, the permittivity of which is relatively high.

The copper lines 21W may be formed through other methods. For example, the contact holes 20 may be formed after the wiring grooves 21.

Ions other than argon ions may be implanted. For example, boron ions or nitrogen ions may be used. Further, inert gas ions, such as helium ions, neon ions, krypton ions, xenon ions, and radon ions, may be used.

In addition, ions other than that of boron and nitrogen may be implanted. More specifically, ions of elements belonging to group 13 (IIIB), group 14 (IVB), group 15 (VB), group 16 (VIB), and group 17 (VIIB) and ions of compounds including such elements may be implanted. Among these ions, ions of at least one of oxygen, aluminum, sulfur, chlorine, gallium, germanium, arsenic, selenium, bromine, antimony, iodine, indium, tin, tellurium, lead, and bismuth is preferred. Further, ions of compounds including at least one of oxygen, aluminum, sulfur, chlorine, gallium, germanium, arsenic, selenium, bromine, antimony, iodine, indium, tin, tellurium, lead, and bismuth is preferred.

Impurities other than ions may be implanted. For example, the inert gases mentioned above or compounds including oxygen, aluminum, sulfur, chlorine, gallium, germanium, arsenic, selenium, bromine, antimony, iodine, indium, tin, tellurium, lead, or bismuth may be implanted.

The composition of the organic SOG film 5a may be changed as required.

A low permittivity film that sufficiently suppresses the dispersion of copper may be formed in lieu of the organic SOG film 5a. For example, a third silicon oxide film (SiO film), the permittivity of which is lower than a silicon nitride film, may be formed in lieu of the organic SOG film 5a. In this case, ions are implanted in the SiO film to form a modified silicon oxide film that sufficiently suppresses the dispersion of copper. Although the relative permittivity of the modified silicon oxide film depends on the semiconductor device 50, it is preferred that the relative permittivity be 4.0 or less.

A film formed from an organic polymer, such as polyimide or poly arylene ether (PAE) may be used as the low permittivity film. In other words, it is required that the film have low permittivity and that impurities be implanted on the film to suppress the dispersion of copper.

The semiconductor device 50 of the preferred embodiment has an upper layer (second silicon oxide film 4) in which the copper lines 21W are formed and a lower wiring layer (substrate 1), which is in via contact with the upper layer 4. However, the semiconductor device is not restricted to such configuration.

The present invention may be applied to any semiconductor device manufactured through the damascene process. For example, if the interlayer dielectric films 2, 3 have a low permittivity and sufficiently suppress the dispersion of copper, the barrier metal 30 may be eliminated. The present invention may also be applied to a semiconductor device that does not have the barrier metal 30. In other words, the present invention is effective for any semiconductor device that has a copper wiring (copper lines 21W).

The silicon oxide films 2, 4 may be formed through a method other than that of the preferred embodiment. It is preferred that a gas including monosilane and oxygen be used when performing atmospheric pressure CVD and that a gas including monosilane and nitrous oxide be used when performing low-pressure CVD.

An dielectric film having high permittivity may be used as long as the film is modified by implanting ions to suppress the dispersion of copper. Although this does not decrease capacitance, materials that could not be used in the prior art may be used to form the dielectric film. Thus, the semiconductor device 50 may be designed with fewer restrictions. If the dielectric film has a low permittivity, the dispersion of copper is suppressed, the semiconductor device 50 is enabled to operate at higher speeds, and the semiconductor device 50 is designed with fewer restrictions.

The present examples and embodiments are to be considered as illustrative and not restrictive, and the invention is not to be limited to the details given herein, but may be modified within the scope and equivalence of the appended claims.

What is claimed is:

1. A semiconductor device comprising:
a first dielectric film having an opening;
a line arranged in the opening, wherein the line includes copper; and
a second dielectric film coating at least part of the line, wherein impurities are implanted in the second dielectric film.

2. A semiconductor device comprising:
a first dielectric film having an opening;
a line arranged in the opening, wherein the line includes copper; and
a second dielectric film coating at least part of the line, wherein the second dielectric film is formed from a low permittivity material in which impurities are implanted.

3. The semiconductor device according to claim 2, further comprising:
a barrier metal formed in the opening between the first dielectric film and the line.

4. The semiconductor device according to claim 2, further comprising a barrier metal that covers parts of the line that are not coated by the second dielectric film.

5. The semiconductor device according to claim 2, wherein the low permittivity material includes spin on glass (SOG).

6. A semiconductor device comprising:
a silicon substrate including a first dielectric film, wherein the first dielectric film has an upper surface and a groove;
a copper line formed in the groove and having an upper surface, wherein the upper surface of the copper line is flush with the upper surface of the first dielectric film; and
a second dielectric film coating the upper surface of the copper line and the upper surface of the first dielectric film, wherein impurities are implanted in the second dielectric film.

7. The semiconductor device according to claim 6, wherein the second dielectric film includes a modified silicon compound in which argon ions are implanted.

8. The semiconductor device according to claim 6, further comprising a barrier metal for covering the copper line at parts excluding the upper surface of the line.

9. A method for manufacturing a semiconductor device comprising:
forming a first dielectric film on a lower wiring layer;
forming a groove in the first dielectric film;
filling the groove with copper by way of a barrier metal;
coating at least part of the upper surface of the copper with a low permittivity dielectric material; and
modifying the low permittivity dielectric material by implanting impurities.

10. The method according to claim 9, wherein the low permittivity dielectric material includes spin on glass (SOG), and the coating step includes spin coating.

11. The method according to claim 9, wherein the low permittivity dielectric material is an organic spin on glass solution that includes a solvent and a silicon compound, the method further comprising heating the semiconductor device before modifying the low permittivity dielectric material to eliminate the solvent from the organic spin on glass solution.

12. The method according to claim 9, wherein the implanting of impurities includes:
implanting ions of an element selected from a group consisting of argon, boron, nitrogen, helium, neon, krypton, xenon, radon, oxygen, aluminum, sulfur, chlorine, gallium, germanium, arsenic, selenium, bromine, antimony, iodine, indium, tin, tellurium, lead, and bismuth or implanting ions of a compound including elements selected from the group.

13. The method according to claim 9, the filling of copper includes forming the barrier metal to cover walls of the groove and filling copper in the groove covered by the barrier metal.
